(19) United States
(12) Patent Application Publication
(10) Pub. No.: US 2023/0178551 A1
(43) Pub. Date: Jun. 8, 2023

(54) INTEGRATION OF HORIZONTAL NANOSHEET DEVICE AND VERTICAL NANO FINS

(71) Applicant: INTERNATIONAL BUSINESS MACHINES CORPORATION, ARMONK, NY (US)

(72) Inventors: Tsung-Sheng Kang, Ballston Lake, NY (US); Ruilong Xie, Niskayuna, NY (US); Tao Li, Albany, NY (US); Alexander Reznicek, Troy, NY (US)

(21) Appl. No.: 17/457,271

(22) Filed: Dec. 2, 2021

(51) Int. Cl. H01L 27/092; H01L 29/06; H01L 29/423; H01L 29/786; H01L 21/02; H01L 21/8238; H01L 29/66

(52) U.S. Cl. CPC H01L 27/0922; H01L 29/0665; H01L 29/42392; H01L 29/78696; H01L 21/0259; H01L 21/823807; H01L 21/823828; H01L 29/66742

(57) ABSTRACT

A semiconductor device including a first device that includes a plurality of nanosheets located on top of a substrate, where the plurality of nanosheets includes first number of nanosheets. A second device that a plurality of vertical segments located on the substrate, where the plurality of vertical segments is in the same vertical plane. Wherein the first device and the second device are adjacent to each other. Where the plurality of vertical segments includes a second number of vertical segments and where the first number is larger than the second number.

### BACKGROUND

The present invention generally relates to the field of nano devices, and more particularly to forming horizontal stacked nanosheets NFET adjacent to stacked vertical PFET nano fins.

Nanosheet is the lead device architecture in continuing CMOS scaling. However, nanosheet technology has shown issues when manufacturing a PFET device along with a NFET device. The manufacturing of one device can cause damage to the other device.

### BRIEF SUMMARY

Additional aspects and/or advantages will be set forth in part in the description which follows and, in part, will be apparent from the description, or may be learned by practice of the invention.

A semiconductor device including a first device that includes a plurality of nanosheets located on top of a substrate, where the plurality of nanosheets includes first number of nanosheets. A second device that a plurality of vertical segments located on the substrate, where the plurality of vertical segments is in the same vertical plane. Wherein the first device and the second device are adjacent to each other. Where the plurality of vertical segments includes a second number of vertical segments and where the first number is larger than the second number.

A semiconductor device includes a first device that includes a plurality of nanosheets located on top of a substrate, where the plurality of nanosheets includes first number of nanosheets. A second device that a plurality of vertical segments located on the substrate, where the plurality of vertical segments is in the same vertical plane. Where the first device and the second device are adjacent to each other and where a top surface of a top nanosheet of the plurality of nanosheets is in same horizontal plane as a top surface of a top vertical segment of the plurality of vertical segments. Where the plurality of vertical segments includes a second number of vertical segments and where the first number is larger than the second number.

A method including forming a first device that includes a plurality of nanosheets located on top of a substrate, where the plurality of nanosheets includes first number of nano sheets. Forming a second device that a plurality of vertical segments located on the substrate, where the plurality of vertical segments is in the same vertical plane. Where the first device and the second device are adjacent to each other. Where the wherein the plurality of vertical segments includes a second number of vertical segments and where the first number is larger than the second number.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of a nanosheet device adjacent to a vertical fin device, in accordance with an embodiment of the present invention.

FIG. 2 illustrates cross section A of the adjacent nano devices illustrating an initial nano stack, in accordance with the embodiment of the present invention.

FIG. 3 illustrates cross section A of the adjacent nano devices after removal of portion of the nano stack, in accordance with the embodiment of the present invention.

FIG. 4 illustrates cross section A of the adjacent nano devices after formation of the second device, in accordance with the embodiment of the present invention.

FIG. 5 illustrates cross section A of the adjacent nano devices after patterning of the adjacent devices, in accordance with the embodiment of the present invention.

FIG. 6 illustrates cross section A of the adjacent nano devices after formation of a shallow trench isolation layer, in accordance with the embodiment of the present invention.

FIG. 7 illustrates cross section A of the adjacent nano devices after formation of the dummy gate, in accordance with the embodiment of the present invention.

FIG. 8 illustrates cross section B of the of the second nano device after patterning of the dummy gate, in accordance with the embodiment of the present invention.

FIG. 9 illustrates cross section A of the adjacent nano devices after formation of a top spacer in the second nano device, in accordance with the embodiment of the present invention.

FIG. 10 illustrates cross section B of the second nano devices after formation of the top spacer, in accordance with the embodiment of the present invention.

FIG. 11 illustrates cross section A of the adjacent nano devices after patterning the second device, forming source/drain epitaxy, and forming an inner spacer, in accordance with the embodiment of the present invention.

FIG. 12 illustrates cross section B of the second nano device after patterning the second device, forming source/drain epitaxy, and forming an inner spacer, in accordance with the embodiment of the present invention.

FIG. 13 illustrates cross section A of the adjacent nano devices after forming a shared gate between the devices, in accordance with the embodiment of the present invention.

FIG. 14 illustrates cross section B of the second nano device after formation of the shared gate, in accordance with the embodiment of the present invention.

FIG. 15 illustrates cross section A of the adjacent nano devices after formation of the gate in an alternative embodiment, in accordance with the embodiment of the present invention.

FIG. 16 illustrates cross section B of the second nano devices after formation of the shared gate in the alternative embodiment, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. A single fin tends to have poor electrostatic properties and a stack of nano wires tend not to have enough effective gate width (W_{eff}). Nanosheets tend to have good electrostatic properties but tend to have an increased footprint. Nanosheet architecture is beneficial for NFET for higher electron mobility and FIN architecture is beneficial for PFET for higher hole mobility. The present invention is directed towards forming a nanosheet NFET device adjacent to a vertical fin PFET device. The vertical fin of the PFET device is broken up into multiple segments to increase the interface surface area between the fin and the gate metal. The number of vertical segments of a vertical fin in a PFET device are less than the number of nanosheets used in NFET device. This ratio of segments to nanosheet ensures that the segments are of a large enough size to achieve the necessary W_{eff}. By breaking up the fin into multiple segments allows for better gate control. When there are too many segments than the segments tend to have similar properties as nanowires. Therefore, by keeping the number of vertical segments less than the number of nanosheets ensures that the vertical segments achieve the necessary electrostatic properties and the W_{eff}.

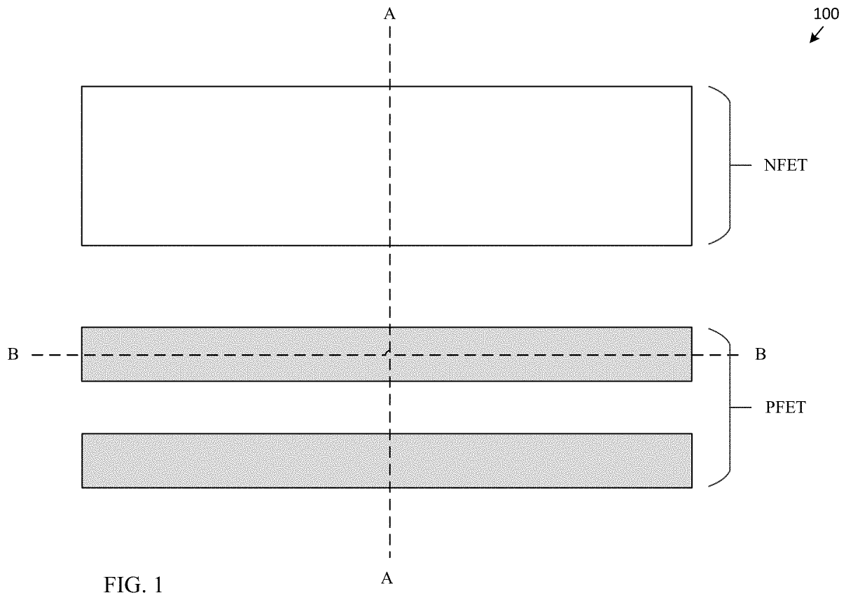

FIG. 1 illustrates a top-down view of a nanosheet device adjacent to a vertical fin device, in accordance with an embodiment of the present invention. The present invention has a NFET nanosheet device that is located adjacent to a vertical fin PFET device. The fin is broken up into multiple vertical segments, or vertical ellipses, to increase the contact surface area with the gate metal that surrounds the fin segments.

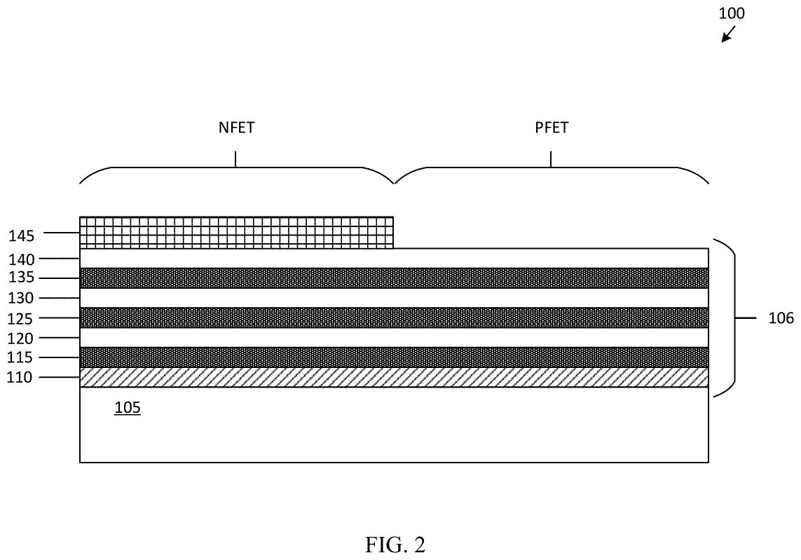

FIG. 2 illustrates cross section A of the adjacent nano devices 100 illustrating an initial nano stack 106, in accordance with the embodiment of the present invention. The adjacent nano devices 100 includes an initial nano stack 106 located on top of a substrate 105. The substrate 105 can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of the semiconductor materials can be used as the semiconductor material of the substrate 105. In some embodiments, the substrate 105 includes both semiconductor materials and dielectric materials. The semiconductor substrate 105 may also comprise an organic semiconductor or a layered semiconductor such as, for example, Si/SiGe, a silicon-on-insulator or a SiGe-on-insulator. A portion or entire semiconductor substrate 105 may also be comprised of an amorphous, polycrystalline, or monocrystalline. The semiconductor substrate 105 may be doped, undoped or contain doped regions and undoped regions therein.

The initial nano stack 106 includes a first layer 110, a second layer 115, a third layer 120, a fourth layer 125, a fifth layer 130, a sixth layer 135, and a seventh layer 140. The first layer 110 can be comprised of, for example, SiGe, where Ge is in the range of about 45% to 70%. The initial nanosheet stack 106 includes a group of sacrificial layers comprised of the second layer 115, the fourth layer 125, the sixth layer 135. Each of the sacrificial layers can be comprised of, for example, SiGe, where Ge is in the range of about 15% to 35%. The initial nanosheet stack 106 includes a group of nanosheets comprised of the third layer 120, the fifth layer 130, the seventh layer 140. Each layer of the group of nanosheets can be comprised of, for example, Si. The NFET section of the initial nano stack 106 is isolated by forming a hardmask 145 on top of the seventh layer 140. The hardmask 145 is patterned so that the hardmask 145 remains where the NFET section is formed and does not remain where the adjacent PFET will be formed.

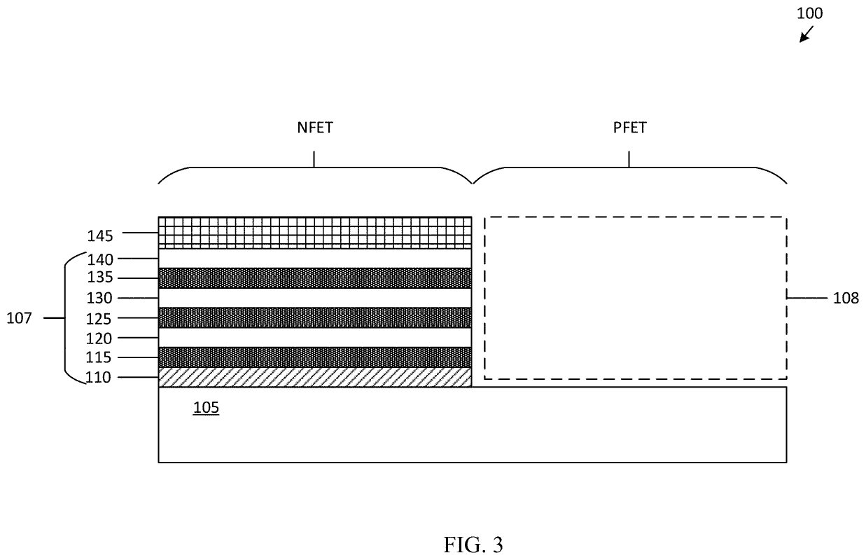

FIG. 3 illustrates cross section A of the adjacent nano devices 100 after removal of portion of the nano stack 106, in accordance with the embodiment of the present invention. The initial nano stack 106 is etched where a portion of the stack is removed. Dashed box 108 illustrates where the portion of the initial nano stack 106 was removed. The hardmask 145 protects a portion of the nano stack 106 from being etched. The NFET nanosheet device is formed from the remaining nano stack 107.

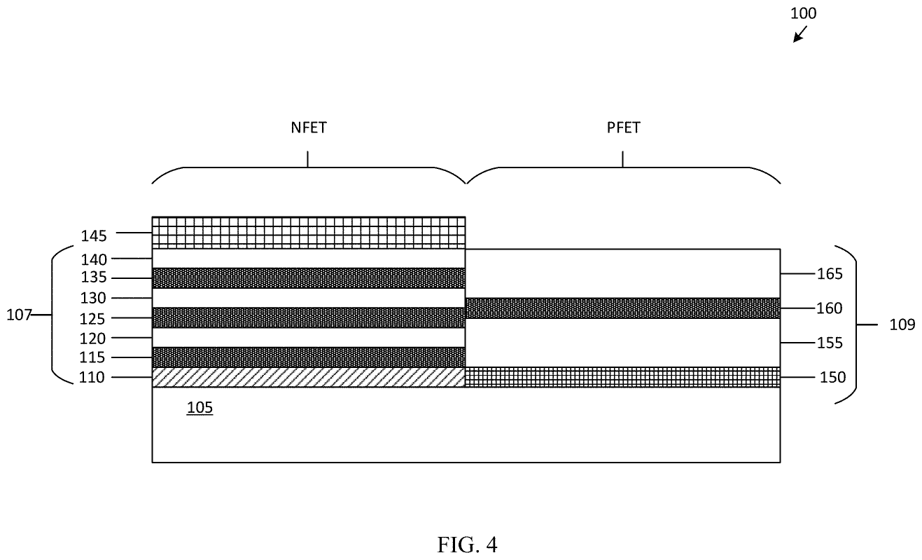

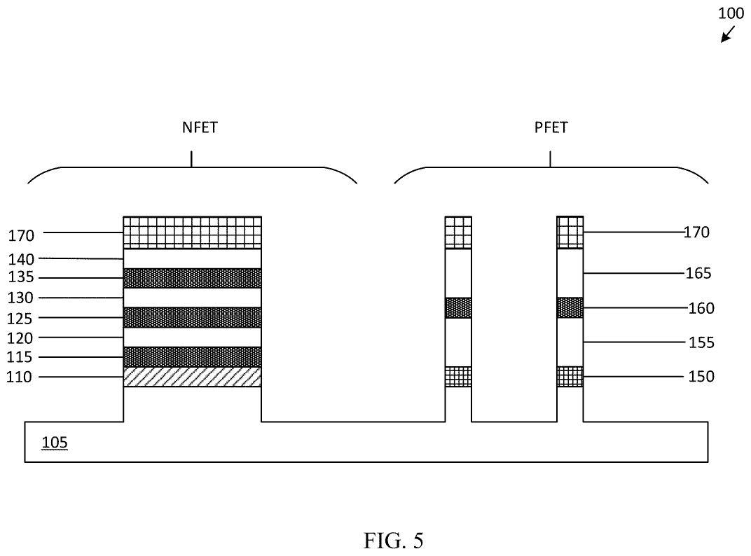

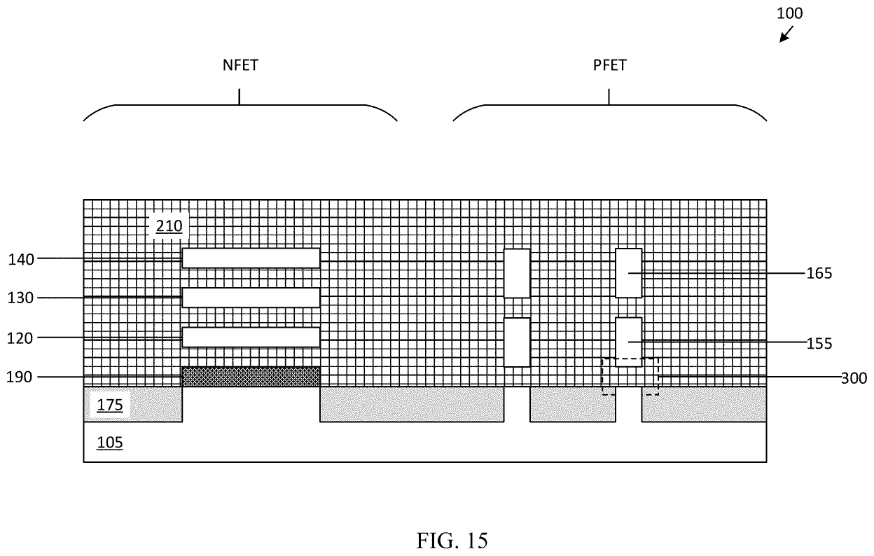

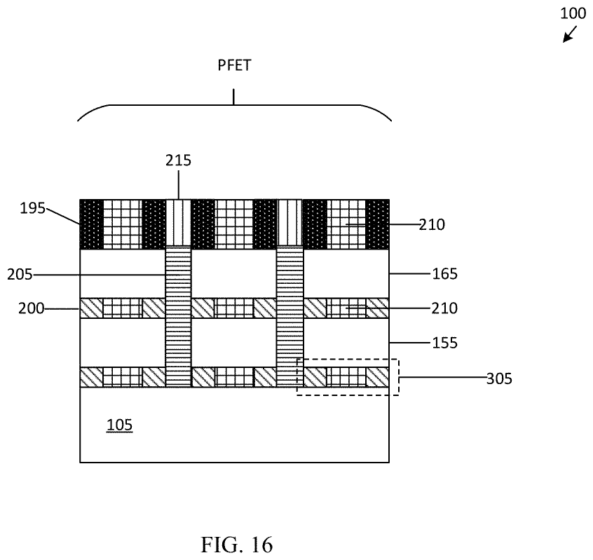

FIG. 4 illustrates cross section A of the adjacent nano devices 100 after formation of the second device, in accordance with the embodiment of the present invention. A new nano stacked 109 is formed in the location where the initial nano stack 106 was removed. The new nano stack 109 forms the foundation of the PFET stacked vertical nano segments. The new nano stack 106 includes a layer A 150, a layer B 155, a layer C 160, and a layer D 165. Layer A 150 can be comprised of, for example, SiGe, where Ge is in the range of about 45% to 70%, or layer A 150 can be comprised of, for example, SiGe, where Ge is in the range of about 15% to 35%. The initial concentration of Ge affects the final structure of the PFET stacked vertical nano segments. FIGS. 5-14 illustrates the manufacturing steps for the adjacent nano devices 100 when layer A 150 is comprised of SiGe, where Ge is in the range of about 45% to 70%. FIGS. 15 and 16 illustrate the final structure of the adjacent nano devices 100 when layer A 150 is comprised of, for example, SiGe, where Ge is in the range of about 15% to 35%.

Layer B 155 and Layer D 165 can be comprised of, for example, Si. Layer C 160 can be comprised of, for example, SiGe, where Ge is in the range of about 15% to 35%. The height of the new nano stack 109 is about the same as the height of the remaining nano stack 107. The thickness of the Layer B 155 and the layer D 165 is greater than the thickness of each of the nanosheet layers (i.e., the third layer 120, the fifth layer 130, and the seventh layer 140). Layer B 155 and layer D 165 will end up as the vertical stack segments of the fin PFET device. The number of nanosheets (i.e., the third layer 120, the fifth layer 130, and the seventh layer 140) is greater than the number of segments (i.e., the layer B 155 and the layer D 165). By having the number of nanosheets being greater than the number of segments, ensures that the segments are a large enough size to have the desired properties and an effective width.

FIG. 5 illustrates cross section A of the adjacent nano devices 100 after patterning of the adjacent devices, in accordance with the embodiment of the present invention. The hardmask 145 is removed and a new hardmask 170 is formed on the top surface of the seventh layer 140 and on top of the layer D 165. The new hardmask 170 is patterned and the underlying layers are etched. The NFET nanosheets are etched to form a wide nanosheet structure and the PFET is etched to one or more fins. The NFET nanosheets can be considered the first device and the PFET stack fin segments can be considered the second device for illustrative purposes only.

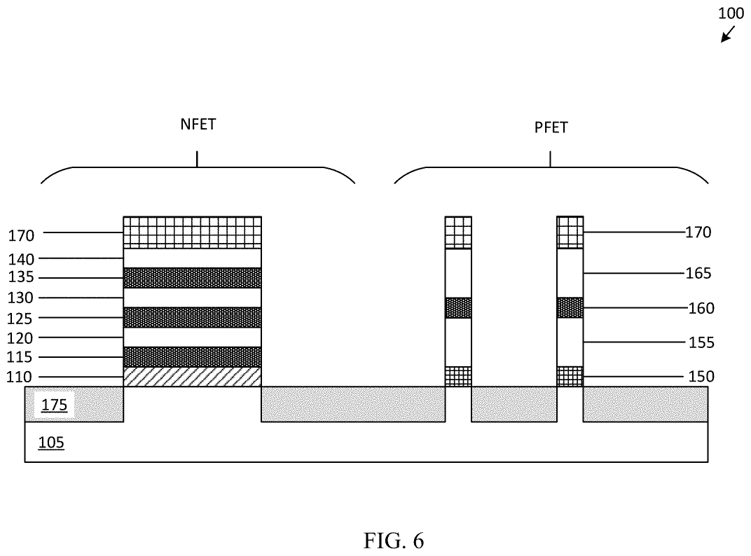

FIG. 6 illustrates cross section A of the adjacent nano devices 100 after formation of a shallow trench isolation layer 175, in accordance with the embodiment of the present invention. A trench is formed in substrate 105 during the etching process to form the NFET nanosheets and the PFET fins. The trench is filled in with a shallow trench isolation layer 175.

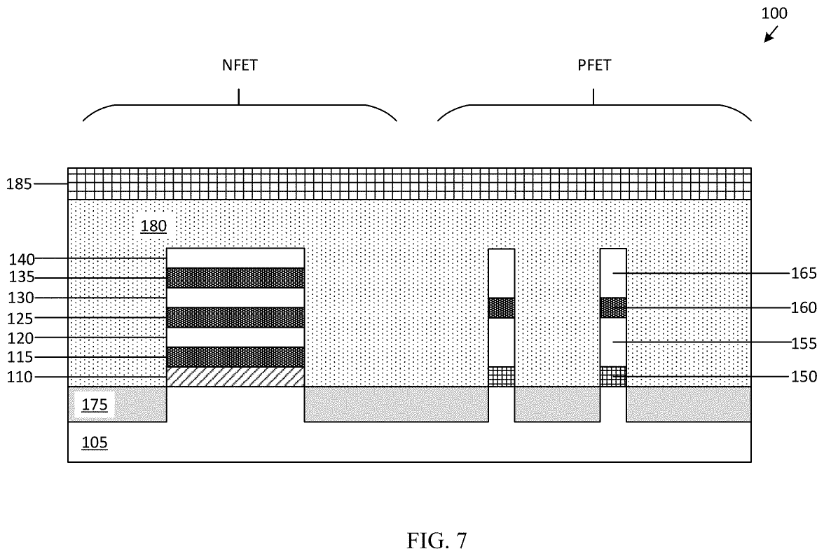

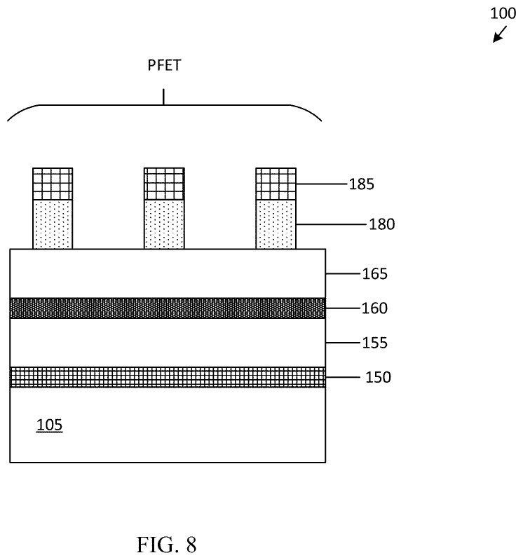

FIG. 7 illustrates cross section A of the adjacent nano devices 100 after formation of the dummy gate 180, in accordance with the embodiment of the present invention. FIG. 8 illustrates cross section B of the second nano device after patterning of the dummy gate 180, in accordance with the embodiment of the present invention. The hardmask 170 is removed and a dummy gate 180 is formed around the NFET nanosheets and the PFET fins. A hardmask 185 is formed on top of the dummy gate 180. As illustrated by FIG. 8, the dummy gate 180 and the hardmask 185 are patterned into one or more columns. Three columns are illustrated in FIG. 8, but this is not meant to be seen as limiting.

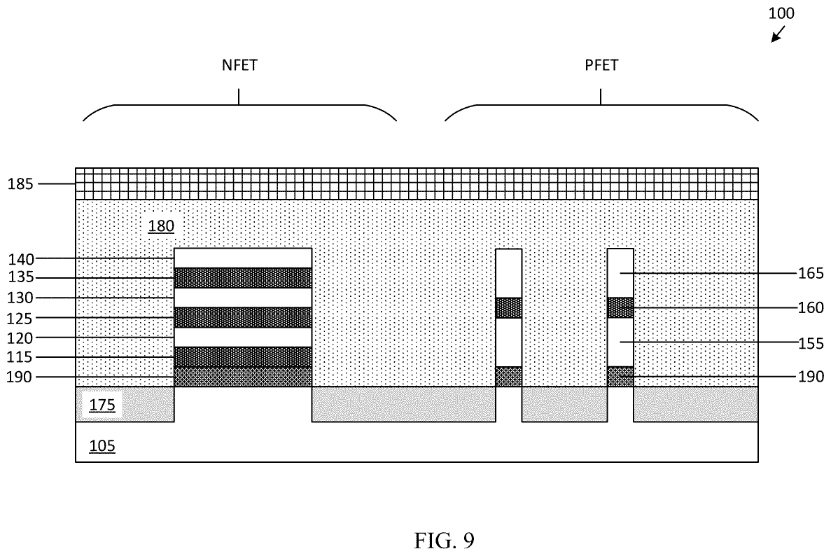

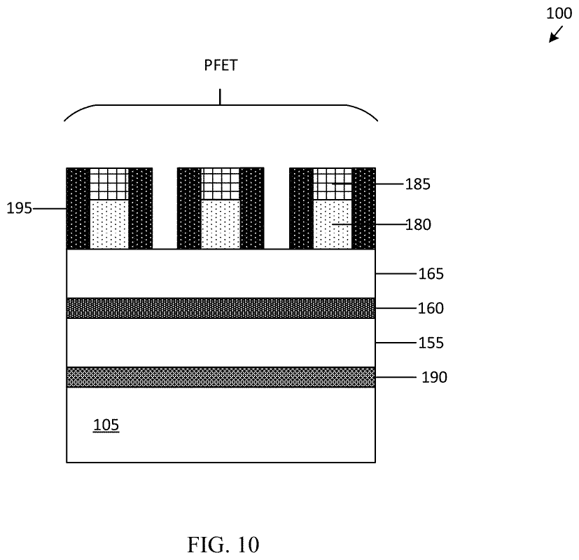

FIG. 9 illustrates cross section A of the adjacent nano devices 100 after formation of a top spacer 195 in the second nano device, in accordance with the embodiment of the present invention. FIG. 10 illustrates cross section B of the second nano device after formation of the top spacer 195, in accordance with the embodiment of the present invention. The first layer 110 and the layer A 150 are selectively removed and replaced with a bottom dielectric layer 190. In the alternative embodiment, when layer A 150 is comprised of SiGe, where Ge is in the range of about 15% to 35%, then layer A 150 is not selectively removed and replaced by the bottom dielectric layer 190. As illustrated by FIG. 10, a top spacer 195 is formed on top of the exposed surfaces of the layer D 165, the dummy gate 180, and the hardmask 185. The top spacer 195 is etched back so that it only remains on the sidewalls of the dummy gate 180 and the hardmask 185.

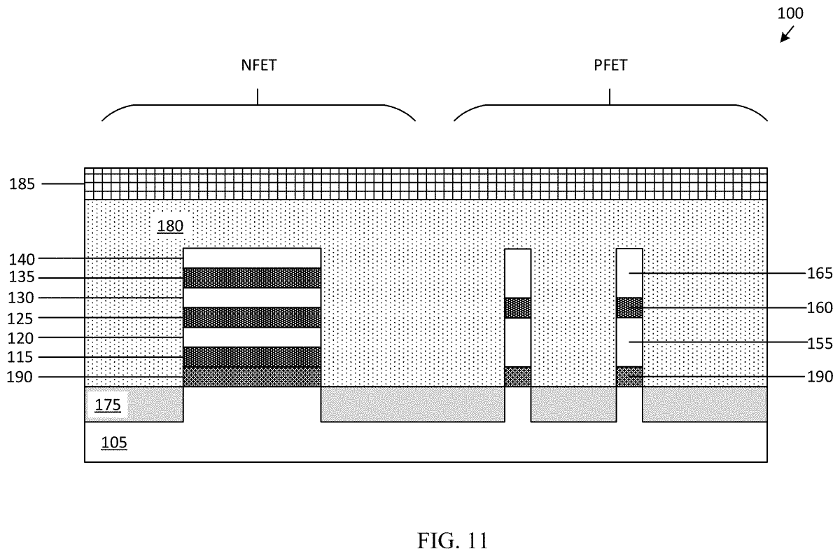

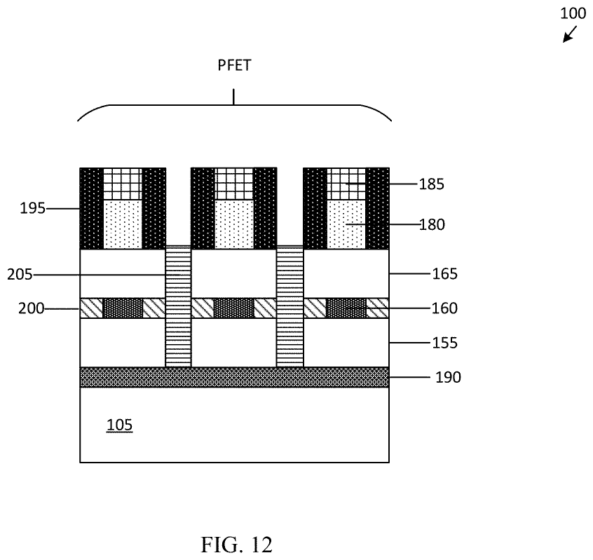

FIG. 11 illustrates cross section A of the adjacent nano devices 100 after patterning the second device, forming source/drain epitaxy 205, and forming an inner spacer 200, in accordance with the embodiment of the present invention. FIG. 12 illustrates cross section B of the second nano device after patterning the second device, forming source/drain epitaxy 205, and forming an inner spacer 200, in accordance with the embodiment of the present invention. Layer C 160 is recessed to create room for the formation of an inner spacer 200. An inner spacer 200 is formed in the space created by the recessing of Layer C 160. A source/drain epitaxy 205 is formed in the space between the columns/pillars. The source/drain epitaxy 205 can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

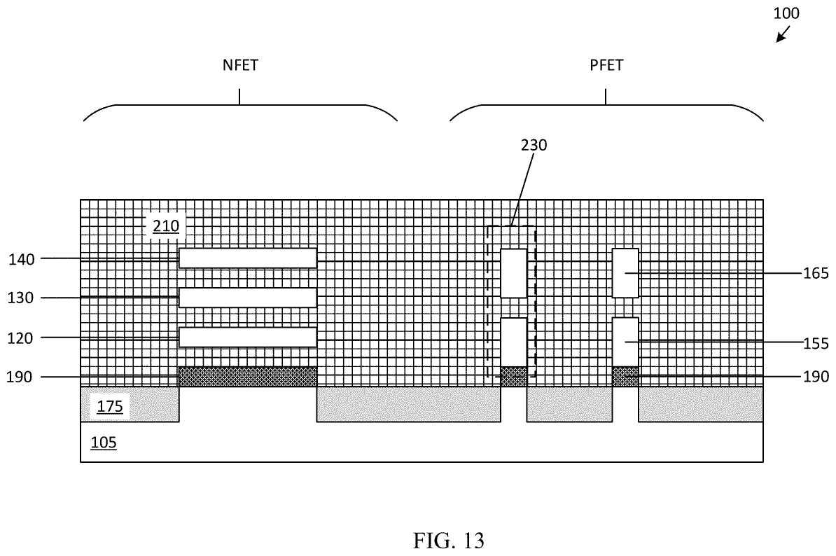

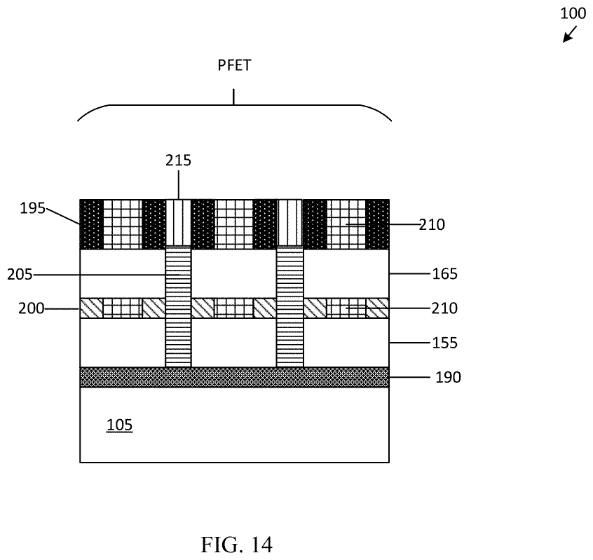

FIG. 13 illustrates cross section A of the adjacent nano devices 100 after forming a shared gate 210 between the devices, in accordance with the embodiment of the present invention. FIG. 14 illustrates cross section B of the second nano device after formation of the shared gate 210, in accordance with the embodiment of the present invention. The hardmask 185 and the dummy gate 180 are removed to expose the underlying layers for each of the devices. The group of sacrificial layers comprised of the second layer 115, the fourth layer 125, the sixth layer 135 and layer C 160 are selectively removed. A shared gate 210 is formed around the third layer 120, the fifth layer 130, the seventh layer 140, layer B 155, and layer D 165. The shared gate 210 can be comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W. FIG. 14 illustrates that the shared gate 210 is formed between layer B 155 and layer D 165. The shared gate 210 is also formed on top of layer D between columns of the top spacer 195. An interlayer dielectric 215 is formed on top of the source/drain epitaxy 205. The bottom dielectric layer 190 is located between the top of the substrate 105 and the bottom surface of the lowest nanosheet (e.g., the third layer 120). As emphasized the vertical segments (e.g., layer B 155 and layer D 165) are in the same vertical plane. When comparing the number of nanosheets (e.g., third layer 120, the fifth layer 130, and the seventh layer 140) to the number of vertical segments located in the same vertical plane. The top surface of the top nanosheet (e.g., the seventh layer 140) is located on the same horizontal plane as the top surface of top vertical segment (e.g., layer D 165).

FIG. 15 illustrates cross section A of the adjacent nano devices 100 after formation of the share gate 210 in an alternative embodiment, in accordance with the embodiment of the present invention. FIG. 16 illustrates cross section B of the second nano devices after formation of the shared gate 210 in the alternative embodiment, in accordance with the embodiment of the present invention. The final structure illustrated in FIGS. 15 and 16 is similar to the structure disclosed in FIGS. 13 and 14, but with couple of variations as illustrated by the first dashed box 300 and the second dashed box 305. When layer A 150 is comprised of, for example, SiGe, where Ge is in the range of about 15% to 35%, then layer A 150 is not replaced with the bottom dielectric layer 190. Layer A 150 is removed with the sacrificial layers, so a space is created under layer B 155. Thus, as the first dash box 300 emphasizes, the shared gate 210 is formed between vertical segments (e.g., layer B 155) and the substrate 105. As illustrated by the second dashed box 305, the inner spacer 200 and the shared gate 210 is located between layer B 155 and the substrate 105.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A semiconductor device comprising:
a first device that includes a plurality of nanosheets located on top of a substrate, wherein the plurality of nanosheets includes first number of nanosheets;
a second device that a plurality of vertical segments located on the substrate, wherein the plurality of vertical segments is in the same vertical plane, wherein the first device and the second device are adjacent to each other, wherein the plurality of vertical segments includes a second number of vertical segments, wherein the first number is larger than the second number.

2. The semiconductor device of claim 1, further comprising:
a shared gate that spans across the first device and the second device.

3. The semiconductor device of claim 2, wherein the shared gate encloses each nanosheet of the plurality of nanosheets.

4. The semiconductor device of claim 2, wherein the shared gate encloses each vertical segment of the plurality of segments.

5. The semiconductor device of claim 1, further comprising:
a bottom dielectric layer located on top of the substrate, wherein the bottom dielectric layer is located between the substrate and the plurality of nanosheets.

6. The semiconductor device of claim 5, wherein the bottom dielectric layer is also located between the substrate and the plurality of vertical segments.

7. The semiconductor device of claim 6, further comprising:
a shared gate that spans across the first device and the second device, wherein the shared gate encloses the first device and encloses the second device.

8. The semiconductor device of claim 7, wherein a portion of the shared gate is located between the substrate and the bottom of the vertical segments.

9. A semiconductor device comprising:
a first device that includes a plurality of nanosheets located on top of a substrate, wherein the plurality of nanosheets includes first number of nanosheets;
a second device that a plurality of vertical segments located on the substrate, wherein the plurality of vertical segments is in the same vertical plane, wherein the first device and the second device are adjacent to each other, wherein a top surface of a top nanosheet of the plurality of nanosheets is in same horizontal plane as a top surface of a top vertical segment of the plurality of vertical segments, wherein the plurality of vertical segments includes a second number of vertical segments, wherein the first number is larger than the second number.

10. The semiconductor device of claim 9, further comprising:
a shared gate that spans across the first device and the second device.

11. The semiconductor device of claim 10, wherein the shared gate encloses each nanosheet of the plurality of nanosheets.

12. The semiconductor device of claim 10, wherein the shared gate encloses each vertical segment of the plurality of segments.

13. The semiconductor device of claim 9, further comprising:
a bottom dielectric layer located on top of the substrate, wherein the bottom dielectric layer is located between the substrate and the plurality of nanosheets.

14. The semiconductor device of claim 13, wherein the bottom dielectric layer is also located between the substrate and the plurality of vertical segments.

15. The semiconductor device of claim 14, further comprising:
a shared gate that spans across the first device and the second device, wherein the shared gate encloses the first device and encloses the second device.

16. The semiconductor device of claim 15, wherein a portion of the shared gate is located between the substrate and the bottom of the vertical segments.

17. A method comprising:
forming a first device that includes a plurality of nanosheets located on top of a substrate, wherein the plurality of nanosheets includes first number of nanosheets;
forming a second device that a plurality of vertical segments located on the substrate, wherein the plurality of vertical segments is in the same vertical plane, wherein the first device and the second device are adjacent to each other, wherein the plurality of vertical segments includes a second number of vertical segments, wherein the first number is larger than the second number.

18. The method of claim 17, further comprising:
forming a shared gate that spans across the first device and the second device.

19. The method of claim 18, wherein the shared gate encloses each nanosheet of the plurality of nanosheets.

20. The method of claim 18, wherein the shared gate encloses each vertical segment of the plurality of segments.
